(19) United States
(12) Patent Application Publication
(10) Pub. No.: US 2005/0059220 A1
(43) Pub. Date: Mar. 17, 2005

(54) Semiconductor device and method of manufacturing the same

(75) Inventor: Hirokazu Fujimaki, Minato-ku (JP)

Correspondence Address: SHINJYU GLOBAL IP COUNSELORS, LLP, 1233 20TH STREET, NW, SUITE 700, WASHINGTON, DC, 20036-2680, US

(73) Assignee: Oki Electric Co., Ltd., Minato-ku (JP)

(21) Appl. No.: 10/937,257

(22) Filed: Sep. 10, 2004

(30) Foreign Application Priority Data
Sep. 17, 2003 (JP) JP 2003-324554

(51) Int. Cl. C30B 1/00

(52) U.S. Cl. 438/478

(57) ABSTRACT

A semiconductor device capable of preventing the occurrence of stress in a field region, and to prevent dislocation, caused by the stress, in the active region is provided. A method for producing a semiconductor includes: forming an active island region (10) on or above an support substrate; forming a field region (20) surrounding a periphery of the active island region (10); forming an interstice portion (112) at boundary between the active island region (10) and the field region (20); subjecting the field region (20) to heat treatment to eject a residual matter to be evaporated after forming the interstice portion (112); and burying the interstice portion (112) by thermal oxidation.

### BACKGROUND OF THE INVENTION

1. Field of the Invention

The present invention relates to a semiconductor device, and a method for producing a semiconductor device. More specifically, the present invention relates to a semiconductor device with an active island region surrounded by a field region, and a method for producing the semiconductor device.

2. Background Information

An SOS (Silicon On Sapphire) structure has been proposed for a semiconductor that is capable of further improving operation speed by reducing the capacitance of a substrate between a substrate and a wire, etc. In addition, when compared to an FET, a bipolar transistor with a high drive performance and low noise characteristic is advantageous for an RF transceiver chip for use with a 5 GHz band LAN (IEE80.211a), UWB (Ultra Wide Band), a GPS system, a high-speed operational amplifier, and so on. Accordingly, it appears that a semiconductor having a bipolar transistor formed on an SOS substrate will become more important in future electronics.

Currently, a vertical bipolar transistor is mainly used for high-frequency operations. However, a thickness of at least 2 μm is required in an active region for a vertical bipolar transistor. Its required thickness is much thicker than that of a CMOS, which conventionally has a required thickness of 0.1 μm. Thus, the thickness of an insulating layer in a field region surrounding the active region requires approximately at least 2 μm of space in such a vertical bipolar transistor. As the thickness of the insulating film increases, its volume also increases. As the volume of the insulating film increases, the amount of film shrinkage also increases during heat treatment. As a result, stress occurs in the insulating film of the field region during the heat treatment of a manufacturing process. This may cause dislocation of components in the crystal structure of the active region.

A method of relieving stress between the films that are part of a semiconductor substrate is disclosed in Japanese Laid-Open Patent Publication No. HEI 05-136017, which is hereby incorporated by reference. Pages 3 and 4 and FIGS. 1-9 of JP05-13017 are especially relevant. The method includes steps for: forming a compound epitaxial layer and a poly-crystal silicon layer on a compound semiconductor substrate; subsequently forming trenches on the compound epitaxial layer and the poly-crystal silicon layer; and finally bonding a single-crystal silicon substrate on the poly-crystal silicon layer. Thus, the trench obviates the boundary stress between the compound semiconductor substrate and the poly-crystal silicon layer caused by the difference between their thermal expansion coefficients in a heat treatment performed after the above process.

An object of the method disclosed in JP05-136017 is to reduce boundary stress between the compound semiconductor substrates that are bonded together caused by the difference between their thermal expansion coefficients, and to prevent exfoliation of the substrates along the boundary. However, JP05-136017 does not address stress that can occur in semiconductor devices whose different regions (an active layer and a field region) with different characteristics are formed in the same layer such as in a vertical bipolar manufacture.

In view of the above, it will be apparent to those skilled in the art from this disclosure that there exists a need for an improved semiconductor device and method for producing the same. This invention addresses this need in the art as well as other needs, which will become apparent to those skilled in the art from this disclosure.

### SUMMARY OF THE INVENTION

Thus, an object of the present invention is to prevent the occurrence of stress in a field region and an active region in a vertical bipolar manufacture of a semiconductor device, and to prevent dislocation caused by stress in the active region.

A method for producing a semiconductor device in accordance with a first aspect of the present invention includes: forming an active island region on or above an support substrate; forming a field region surrounding a periphery of the active island region; forming an interstice portion at a boundary between the active island region and the field region; subjecting the field region to heat treatment to eject a residual matter to be evaporated after forming the interstice portion; and burying the interstice portion by thermal oxidation.

A method for producing a semiconductor device in accordance with a second aspect of the present invention includes: forming an active island region on or above an support substrate; forming a field region surrounding a periphery of the active island region; forming a trench surrounding the periphery of the active island region in the field region; subjecting the field region to heat treatment to eject a residual matter to be evaporated after forming the trench; and burying the trench after subjecting the field region to heat treatment.

A method for producing a semiconductor device in accordance with a third aspect of the present invention is the method of the first or second aspect, wherein the heat treatment is performed in the state that the active region and the field region are separated from each other by the interstice portion. Thus, stress on the members of the field region that could cause film shrinkage is relieved before the interstice portion is buried by thermal oxidation. Therefore it is possible to prevent occurrences of stress in the field region, and to prevent dislocation caused by the film shrinkage of the field region in the crystal structure of the active region.

A method for producing a semiconductor device in accordance with a fourth aspect of the present invention is the method of the first to third aspects, wherein, the trench is formed in the field region to surround the active region. Further, the heat treatment is performed in a state in which the volume of the field region in contact with the active region is small. Thus, the amount of the film shrinkage of the field region in contact with the active region is reduced. Therefore, it is possible to prevent dislocation caused by the film shrinkage in the crystal structure of the active region.

These and other objects, features, aspects, and advantages of the present invention will become apparent to those skilled in the art from the following detailed description, which, taken in conjunction with the annexed drawings, discloses a preferred embodiment of the present invention.

### BRIEF DESCRIPTION OF THE DRAWINGS

Referring now to the attached drawings which form a part of this original disclosure:

FIG. 1 is a cross-sectional view that illustrates a process of a method for producing a semiconductor device in accordance with a first preferred embodiment of the present invention;

FIG. 2 is a cross-sectional view that illustrates a second process of the method for producing a semiconductor device;

FIG. 3 is a cross-sectional view that illustrates a third process of the method for producing a semiconductor device;

FIG. 4 is a cross-sectional view that illustrates a fourth process of the method for producing a semiconductor device;

FIG. 5 is a cross-sectional view that illustrates a fifth process of the method for producing a semiconductor device;

FIG. 6 is a cross-sectional view that illustrates a sixth process of the method for producing a semiconductor;

FIG. 7 is a cross-sectional view that illustrates a seventh process of the method for producing a semiconductor device;

FIG. 8 is a cross-sectional view that illustrates an eighth process of the method for producing a semiconductor device;

FIG. 9 is a cross-sectional view that illustrates a ninth process of the method for producing a semiconductor device;

FIG. 10 is a cross-sectional view that illustrates a tenth process of the method for producing a semiconductor device;

FIG. 11 is a cross-sectional view that illustrates a sixth process of a method for producing a semiconductor device in accordance with a second preferred embodiment of the present invention;

FIG. 12 is a cross-sectional view that illustrates a seventh process of the method for producing a semiconductor device according to the second embodiment;

FIG. 13 is a cross-sectional view that illustrates an eighth process of the method for producing a semiconductor device according to the second embodiment;

FIG. 14 is a cross-sectional view that illustrates a ninth process of the method for producing a semiconductor device according to the second embodiment;

FIG. 15 is a cross-sectional view that illustrates a ninth process of a method for producing a semiconductor device in accordance with a third preferred embodiment of the present invention;

FIG. 16 is a cross-sectional view that illustrates a tenth process of the method for producing a semiconductor device according to the third embodiment;

FIG. 17 is a cross-sectional view that illustrates a fifth process of a method for producing a semiconductor device in accordance with a fourth preferred embodiment of the present invention;

FIG. 18 is a cross-sectional view that illustrates a sixth process of the method for producing a semiconductor device according to the fourth embodiment;

FIG. 19 is a cross-sectional view that illustrates a seventh process of the method for producing a semiconductor device according to the fourth embodiment;

FIG. 20 is a cross-sectional view that illustrates an eighth process of the method for producing a semiconductor device according to the fourth embodiment;

FIG. 21 is a cross-sectional view that illustrates a ninth process of the method for producing a semiconductor device according to the fourth embodiment;

FIG. 22 is a plan view of a semiconductor device according to the fourth embodiment;

FIG. 23 is a plan view of a semiconductor device in accordance with a fifth preferred embodiment of the present invention;

FIG. 24 is a plan view of a semiconductor device in accordance with a sixth preferred embodiment of the present invention;

FIG. 25 is a plan view of a semiconductor device in accordance with a seventh preferred embodiment of the present invention; and

FIG. 26 is a cross-sectional view illustrating a method for producing a semiconductor device in accordance with an eighth preferred embodiment of the present invention.

### DETAILED DESCRIPTION OF THE PREFERRED EMBODIMENTS

Selected embodiments of the present invention will now be explained with reference to the drawings. It will be apparent to those skilled in the art from this disclosure that the following descriptions of the embodiments of the present invention are provided for illustration only and not for the purpose of limiting the invention as defined by the appended claims and their equivalents.

### First Embodiment

Method for Producing

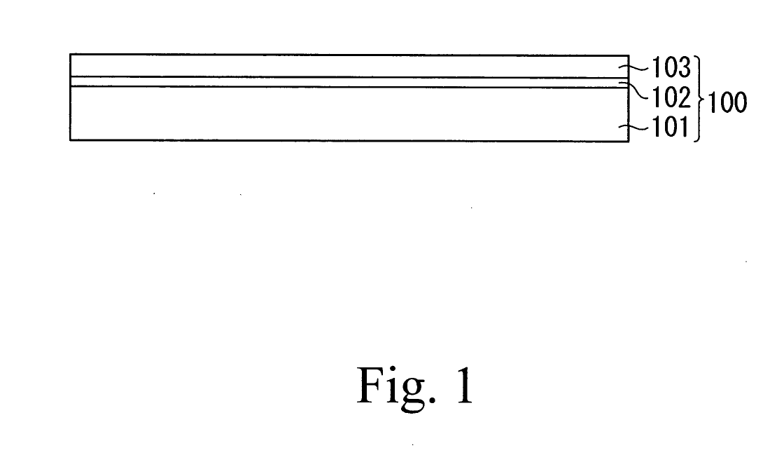

FIGS. 1 to 10 are cross-sectional views illustrating a method for producing a semiconductor device in accordance with a first preferred embodiment of the present invention. First, as shown in FIG. 1, an SOS (Silicon On Sapphire) substrate 100 is prepared. The SOS substrate 100 includes a sapphire substrate (support substrate) 101, a silicon layer 102 of amorphous silicon formed on the sapphire substrate 101, and a single crystal silicon layer 103 formed on the silicon layer 102. The single silicon layer 103 has a thickness of about 0.1 μm and <100>facet.

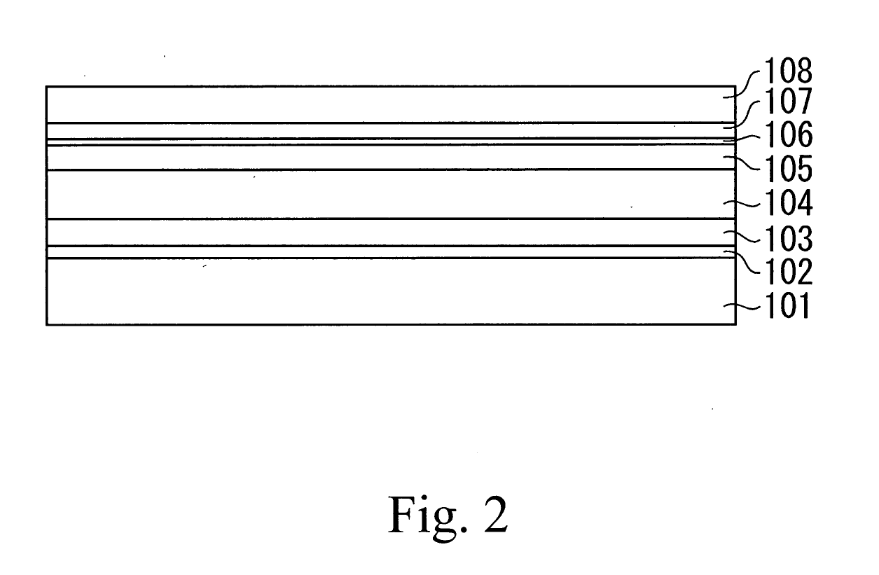

As shown in FIG. 2, a single crystal silicon layer 104 having a thickness of 2.0 μm is epitaxially grown using a doping gas. Further, the single crystal silicon layer 104 has As (arsenicum) with a density therein of 1×10²⁰/cm³. The doping gas is then stopped, and subsequently, a single crystal silicon layer 105 with As residual concentration of not more than 5×10¹⁶/cm³ and with a thickness of 500 nm is grown. In addition, a thermal oxide layer (first thermal oxide film) 106 is formed by subjecting the epitaxial layer of the single crystal silicon layer 105 with a thickness of about 20 nm from its surface to thermal oxidation. After a CVD nitride layer (first insulating film) 107 is formed with a thickness of 200 nm by a CVD (Chemical Vapor Deposition) method, a CVD oxide layer (second insulating film) 108 is formed having a thickness of about 100 nm.

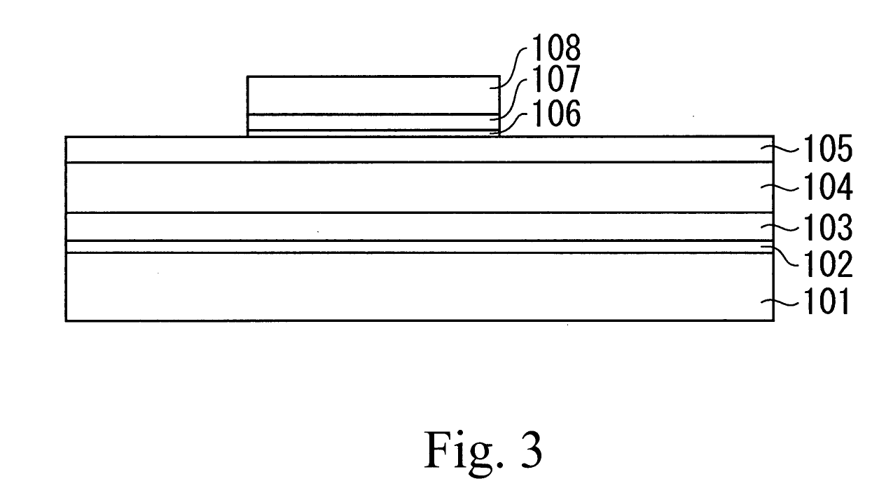

Next, as shown in FIG. 3, a resist pattern is formed on the CVD oxide layer 108 in order to expose an active region. Then, the CVD oxide layer 108, the CVD nitride layer 107, and the thermal oxide layer 106 are etched successively with the resist pattern acting as a mask, and the single crystal silicon layer 105 is exposed.

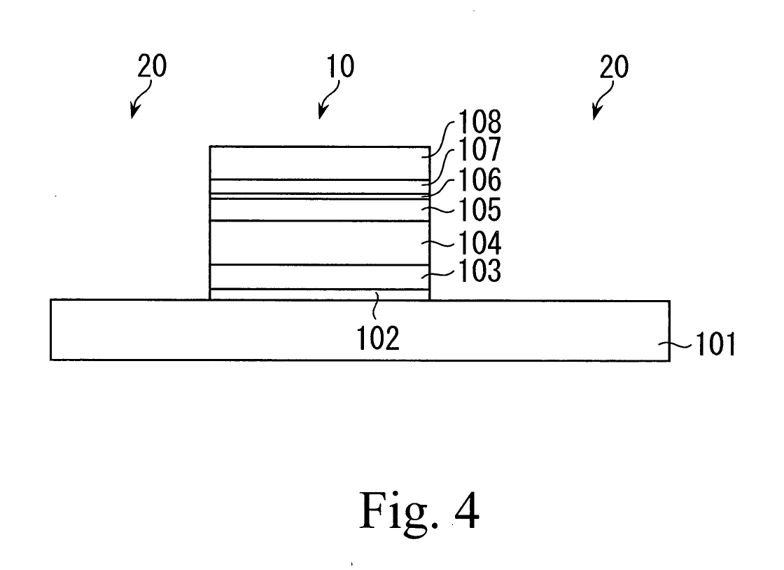

Next, as shown in FIG. 4, the single crystal silicon layers 105, 104, and 103 and the silicon layer 102 are successively etched with the CVD oxide layer 108 acting as a hard mask, exposing the sapphire substrate 101. Thus, an active (island) region 10 and a field region 20 are formed to be divided from each other.

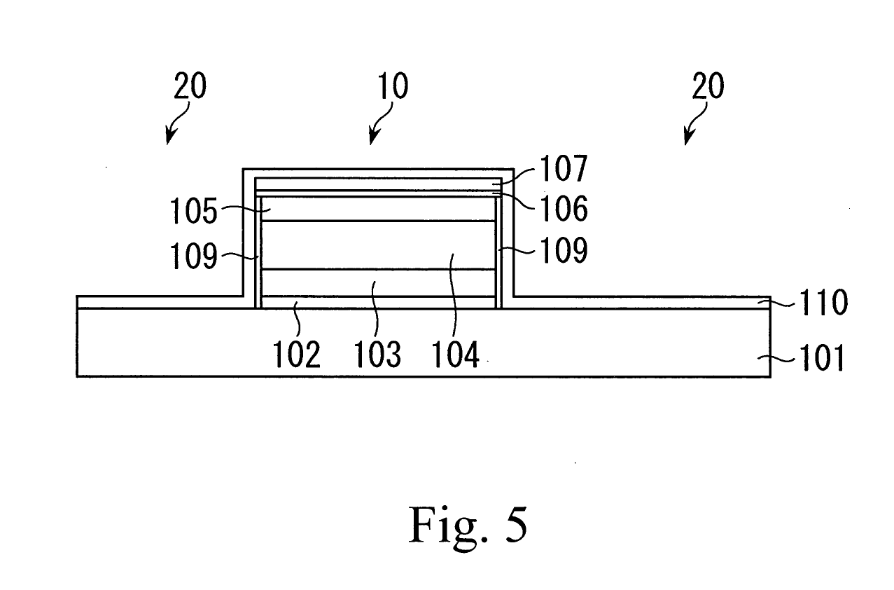

Referring now to FIGS. 4 and 5, after that, the CVD oxide layer 108 that was used as a mask is removed. A thermal oxide film 109 is formed by shallowly subjecting the exposed side surface of the silicon layers to thermal oxidation, and then a CVD nitride film (third insulating film) 110 with a thickness of about 100 nm is entirely formed.

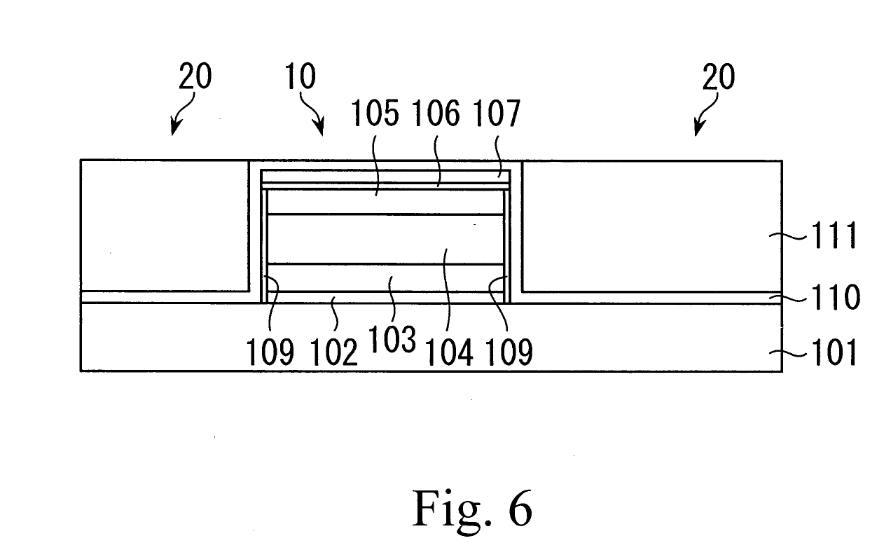

Subsequently, referring to FIGS. 5 and 6, a field oxide film (CVD film) 111 with a thickness of 3.0 μm is formed on the entire surface by a HDP (High Density Plasma) CVD method. Then the wafer surface is polished or reduced by a CMP (Chemical Mechanical Polishing) method, and the polishing is halted based on detecting the CVD nitride film 110. After that, the field oxide film 111 is formed as shown in FIG. 6. This field oxide 111 has a thickness of not less than 2.0 μm.

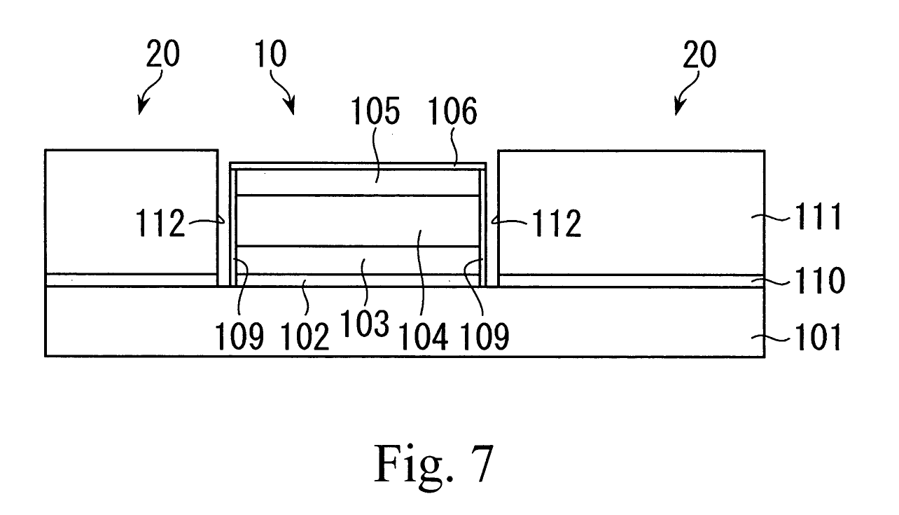

Subsequently, as shown in FIGS. 6 and 7, the CVD nitride film 107 and a portion of the CVD nitride film 110, which remain on the top surface of the active region 10, and a portion of the CVD nitride film 110 formed on the side surface of the active region 10 are removed by a thermal phosphoric acid treatment. Thus, an interstice portion 112 is formed between the active region 10 and the field region 20, as shown in FIG. 7.

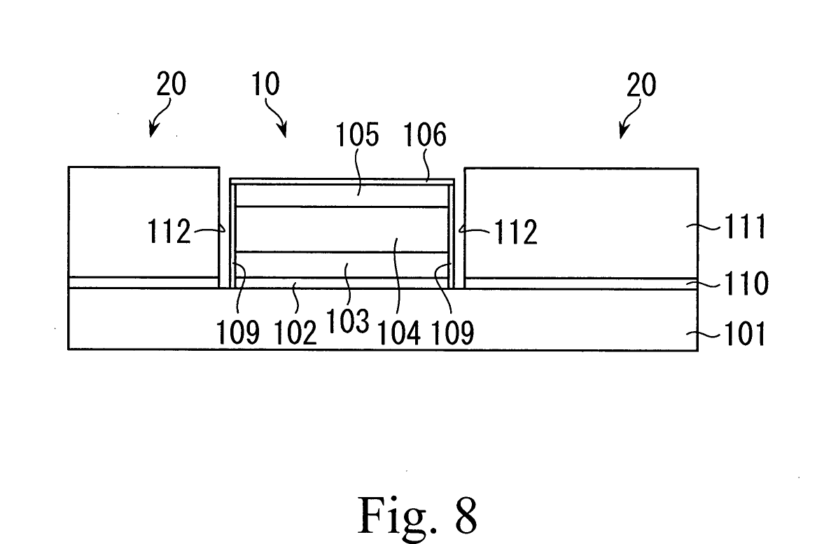

Subsequently, as shown in FIGS. 7 and 8, an annealing process at the maximum heat load (temperature) available for this method for producing a semiconductor device, or an annealing process capable of sufficiently ejecting an internal residual matter to be evaporated such as moisture from the field oxide 111 is performed as a heat treatment in order to relieve the internal stress of the field oxide 111. For example, the above annealing process is performed under a nitrogen N₂ atmosphere at a temperature of 1000° C. for 30 minutes. As result of this heat treatment, matter to be evaporated is sufficiently ejected from the field oxide 111, and film shrinkage of the field oxide 111 is achieved. Accordingly, the interstice portion 112 between the active region 10 and the field region 20 is expanded as shown in FIG. 8.

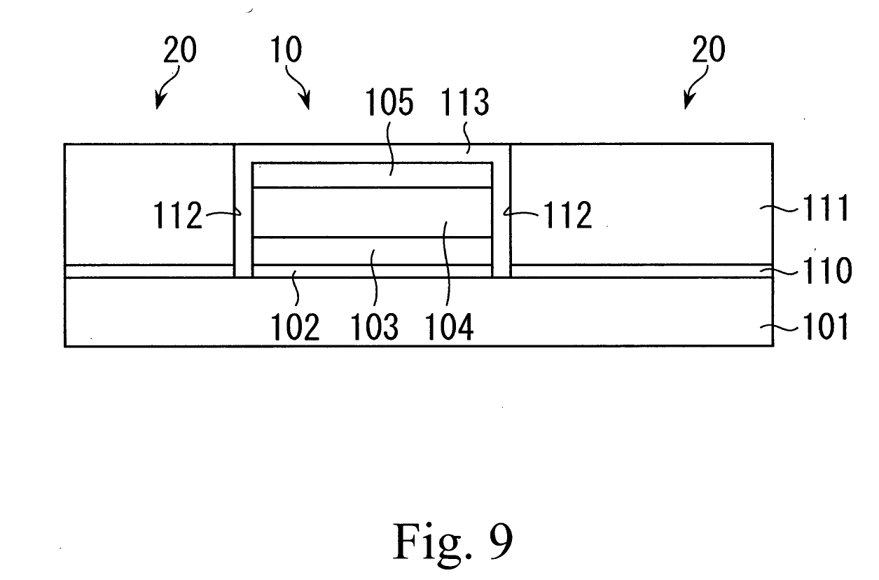

Subsequently, as shown in FIG. 9, the interstice portion 112 is buried by a thermal oxidation layer (first insulating film) 113 by thermal oxidation. In addition, when the width of the interstice portion 112 is 0.8 μm or less, an LP-TEOS (Low Pressure-Tetra Ethyl OrthoSilicate) film could be used to bury the interstice portion 112. Further, the oxidation layer 113 in the interstice portion 112 may be formed by annealing and etchback. Additionally, voids or holes may occur in the buried interstice portion 112 without any detrimental effects.

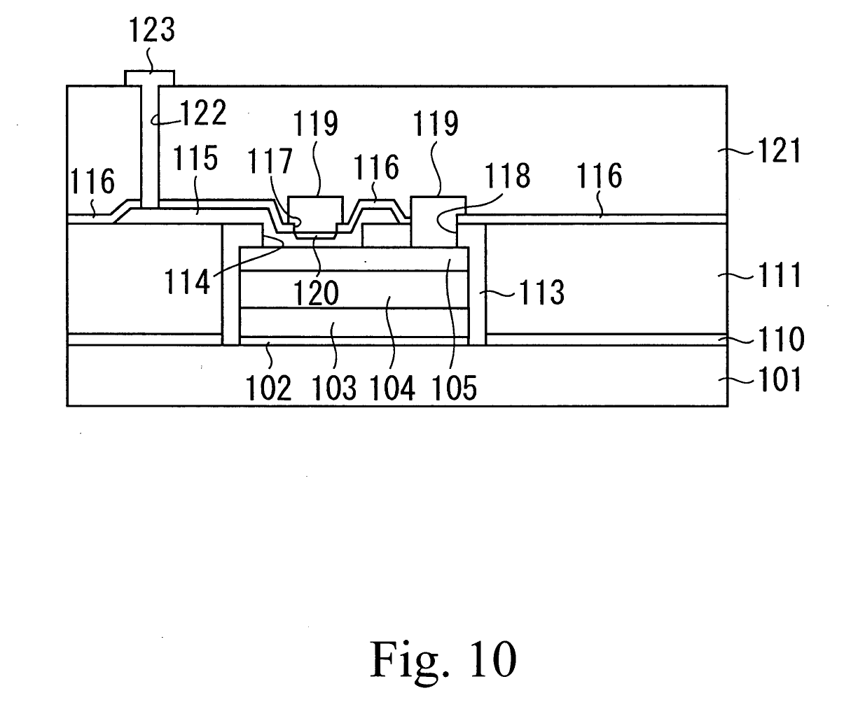

As shown in FIG. 10, after that, the field region 20, which is completely separated from the vertical bipolar transistor and a substrate potential, is formed by a well-known method for producing of a bipolar transistor. Thus, as an example, a bipolar transistor can be produced as follows. First, after an opening 114 is formed in the thermal oxide layer 113 and the single crystal silicon layer 105 is exposed, a silicon layer 115 containing B (Boron) is entirely deposited thereon. At this time, polycrystalline silicon is deposited on the insulated films (the thermal oxide film 113 and the field oxide 111), and single crystal silicon is deposited on the single crystal silicon layer 105. After that, this silicon layer is patterned as shown in FIG. 10. Subsequently, the exposed silicon surface layer is shallowly subjected to oxidization, and a silicon nitride layer 116 is entirely deposited thereon. Subsequently, the silicon nitride layer 116 is patterned to form an opening 117 for an emitter electrode. Thereafter, an opening 118 for a collector electrode is formed. Subsequently, polycrystalline silicon 119 with doped arsenic As is deposited, preferably on the entire surface. This polycrystalline silicon layer 119 is patterned to form the emitter electrode and the collector electrode. Then, an active emitter layer 120 is diffused by heat treatment. Finally, after an interlayer insulating 121 film is formed, an opening 122 is formed on the interlayer insulating film 121 to expose the silicon layer 115, and then a base electrode 123 is formed in the opening 122.

Operation/Working-Effect

When a vertical bipolar transistor is formed in accordance with this embodiment, it is necessary to form completely a field oxide film on the field region in order to reduce capacitance to the substrate. Thus, the thickness of the field oxide is 2.0 μm or more. When the thickness of the field oxide is relatively thick and its volume is large, film shrinkage may occur due to evaporation of residual moisture in the field oxide during subsequent heat treatment at high-temperatures, even if an HDP oxide film as a preferable field oxide film is used. Film shrinkage of field oxide causes a great stress in an active region, and causes dislocation in the active region. This may markedly reduce yields of the semiconductor device. On the contrary, in this embodiment, the interstice portion 112 is formed between the active region 10 and the field region 20 whereby the active region 10 is not in contact with the field region 20. Thus, film shrinkage of the field oxide 111 is achieved so that the matter to be evaporated, such as residual moisture, in the field oxide 111 is sufficiently ejected. Accordingly, the internal stress of the field oxide 111 can be relieved without causing stress on the active region 10. As a result, when a vertical bipolar transistor is produced on the SOS substrate 100, the stress of the field oxide 111 with great thickness can be relieved. Thus, it is possible to prevent crystal dislocation in the active region 10 caused by the stress. Consequently, it is possible to prevent yield deterioration, and to reduce the capacitance to the substrate, in a semiconductor device.

Comparatively, in the structure disclosed in the Japanese Laid-Open Publication No. HEI 05-136017, forming a trench as a scribing line to divide a wafer into semiconductor chips reduces the stress in the boundary direction between bonded substrates. In such a structure, the stress in the active region, which is a much smaller unit than a semiconductor chip unit, is not considered. Accordingly, such a structure cannot reduce the stress in the active region. In contrast, in this embodiment, the interstice portion is provided between the active region and the field region as mentioned above. Thus, it is possible to reduce the stress in the active region.

As used herein, the following directional terms “forward, rearward, above, downward, vertical, horizontal, below, and transverse” as well as any other similar directional terms refer to those directions of a device equipped with the present invention. Accordingly, these terms, as utilized to describe the present invention should be interpreted relative to a device equipped with the present invention.

### Alternate Embodiments

Alternate embodiments will now be explained. In view of the similarity between the first and alternate embodiments, the parts of the alternate embodiment that are identical to the parts of the first embodiment will be given the same reference numerals as the parts of the first embodiment. Moreover, the descriptions of the parts of the alternate embodiments that are identical to the parts of the first embodiment may be omitted for the sake of brevity.

### Second Embodiment

Method for Producing

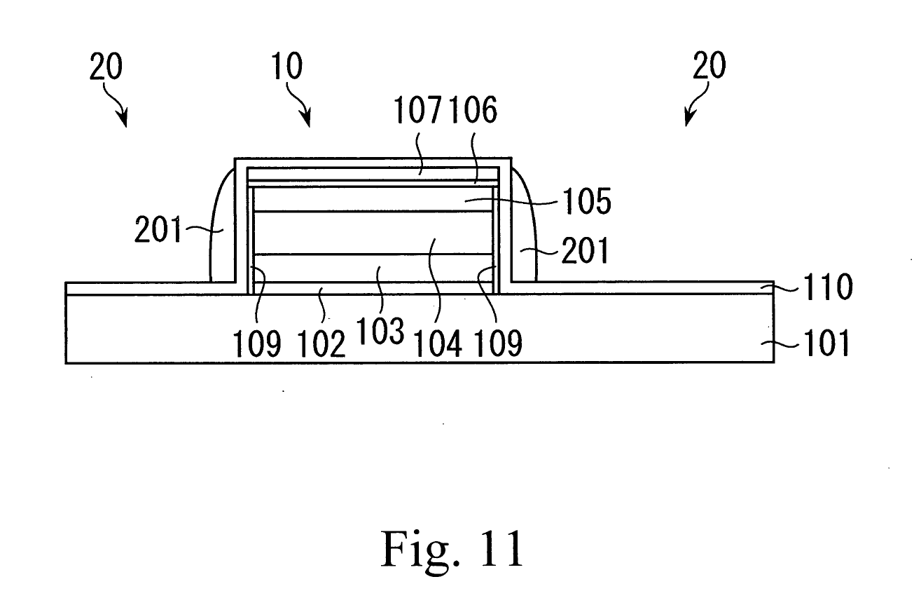

FIGS. 11 to 14 illustrate a method for producing a semiconductor device in accordance with a second preferred embodiment of the present invention. The first five processes of the second embodiment are similar to or the same as the first five processes of the first embodiment shown in FIGS. 1 to 5.

In this embodiment, after the CVD nitride layer 110 is entirely formed in the process shown in FIG. 5, polycrystalline silicon with thickness of about 150 nm is entirely formed over the entire CVD nitride layer 110. As shown in FIG. 11, after that, etchback is performed so that the polycrystalline silicon film 201 remains only on the side wall portions of the active region 10 in a sidewall shape.

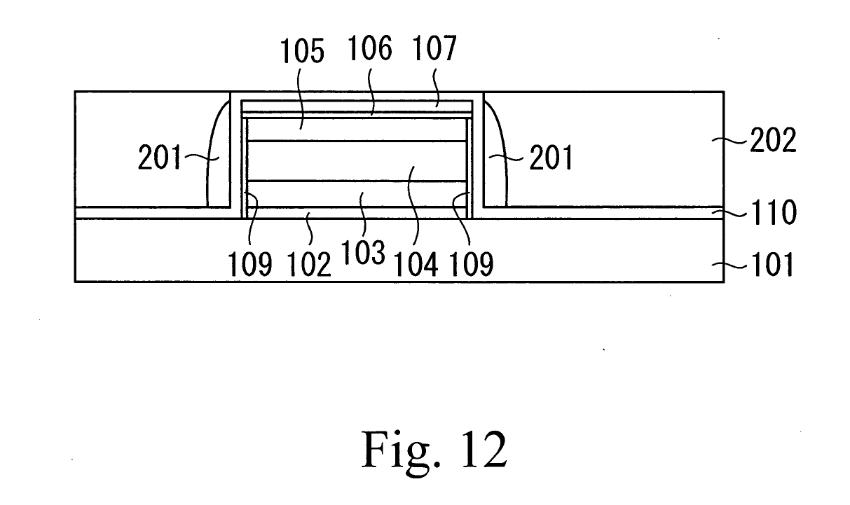

Subsequently, referring to FIG. 12, a field oxide film of about 3.0 μm is formed over the entire surface. Then polishing is performed thereto by a CMP method. The polishing is halted based on the detection of the CVD nitride film 107. After that, a field oxide film 202 is formed. This field oxide film 111 has a thickness of not less than 2.0 μm.

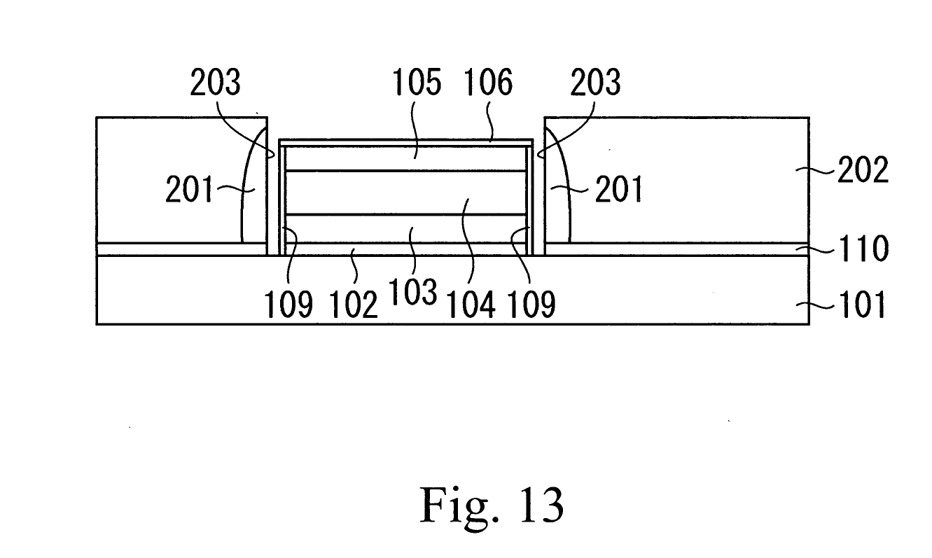

Subsequently, as shown in FIGS. 12 and 13, the CVD nitride film 107 and a portion of the CVD nitride film 110, which is exposed on the top surface of the active region 10, and a portion of the CVD nitride film 110 on the side surface of the active region 10 are removed by a thermal phosphoric acid treatment. Thus, an interstice portion 203 is formed between the active region 10 and the field region 20, as shown in FIG. 13.

Subsequently, heat treatment similar to or the same as that described in the first embodiment causes a slight amount of film shrinkage of the field oxide 202 in order to relieve the internal stress of the field oxide 202. However, in this embodiment, since the polycrystalline silicon film 201 is buried in the wall surface, which is exposed in the interstice portion 203 of the field oxide 202, the shrinkage of the field oxide 202 is small in the interstice portion 203 side. Accordingly, the interstice portion 203 is not enlarged to the degree as that of the first embodiment.

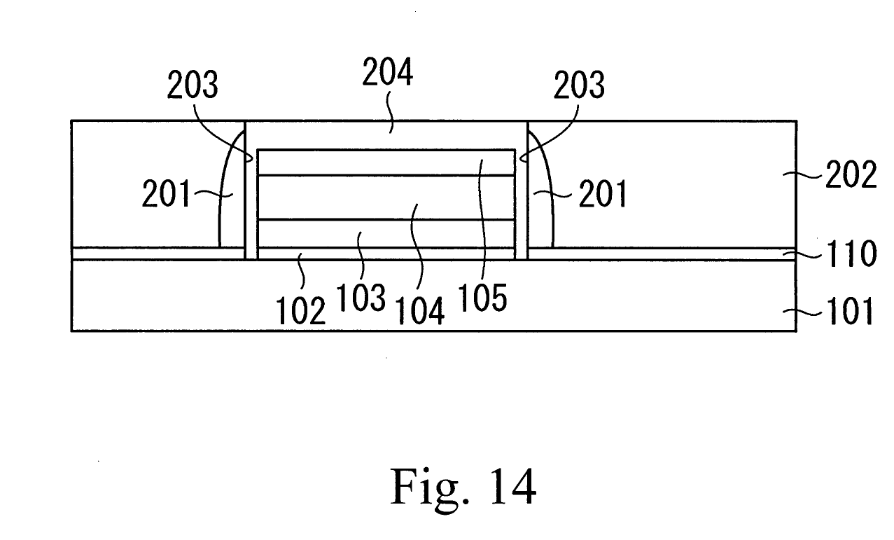

After that, as shown in FIG. 14, the interstice portion 203 is completely buried by subjecting the exposed side portion of the active region 10 and the polycrystalline silicon film 201 to thermal oxidation. The thickness of this oxide film can be about half the thickness as that of the first embodiment. The remaining processes are similar or the same as those of the first embodiment

Operation/Working-Effect

In this embodiment, similar to the first embodiment, when a vertical bipolar transistor is produced on the SOS substrate 100, the stress of the field oxide with a great thickness can also be relieved. Thus, it is possible to prevent crystal dislocation in the active region 10 caused by the stress. Additionally, in this embodiment, since the interstice portion 203 is not enlarged to extent as in the first embodiment during the heat treatment of the field oxide 202, the thermal oxide film 204 to bury the interstice portion 203 can be thin. Accordingly, it is possible to ensure the burial of the interstice portion 203 by thermal oxidation.

### Third Embodiment

Method for Producing

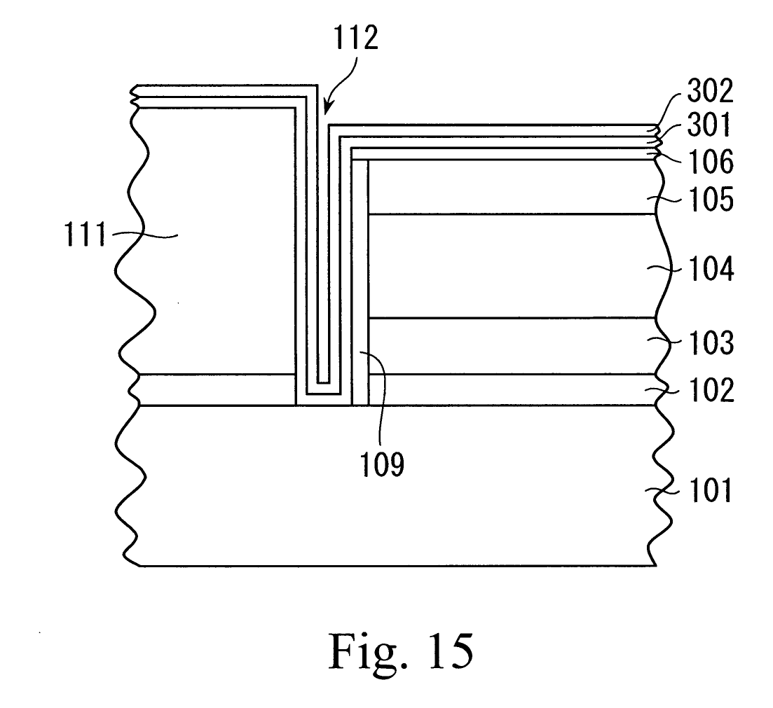

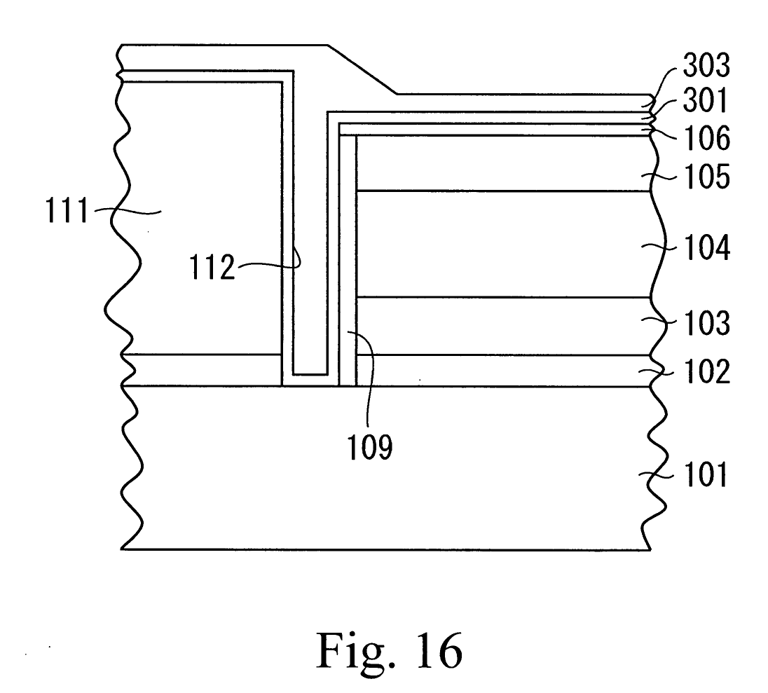

FIGS. 15 and 16 illustrate a method for producing a semiconductor device in accordance with a third embodiment of the present invention. The first eight processes of the third embodiment are similar to or the same as those of the first embodiment shown in FIGS. 1 to 8.

With reference to FIG. 8, after the Field oxide 111 is subjected to heat treatment and the interstice portion 112 is expanded, a thin CVD nitride layer (fourth insulating film) 301 with a thickness of 50 nm is formed on the entire surface, as shown in FIG. 15. Then a polycrystalline silicon layer 302 with thickness of about 100 nm is continuously formed on the CVD nitride layer 301.

Subsequently, as shown in FIG. 16, a (second) thermal oxide film 303 with a thickness of about 250 nm is formed by subjecting the polycrystalline silicon layer 302 to thermal oxidation. Thus, the polycrystalline silicon layer 302 in the active region 10 is totally thermally oxidized, and the interstice portion 112 of the side portion of the active region 10 is also buried by the thermal oxide film 303. At this time, the polycrystalline silicon may partially remain. The remaining processes are the same as or similar to those of the first embodiment

Operation/Working-Effect

In this embodiment, similar to the first embodiment, when a vertical bipolar transistor is produced on the SOS substrate 100, the stress of the field oxide with a great thickness can be also relieved. Thus, it is possible to prevent crystal dislocation in the active region 10 caused by stress.

In addition, in this embodiment, since the CVD nitride layer 301 entirely covers the active region 10 and the polycrystalline silicon layer 302 thereon is thermally oxidized, it is possible to reduce influence on the active region 10 caused by thermal oxidation. Additionally, even when the interstice portion 112 is large, adjusting the thickness of the polycrystalline silicon layer 302 and the amount of the thermal oxidation can be easily conducted to ensure the burial of the interstice portion 112.

### Fourth Embodiment

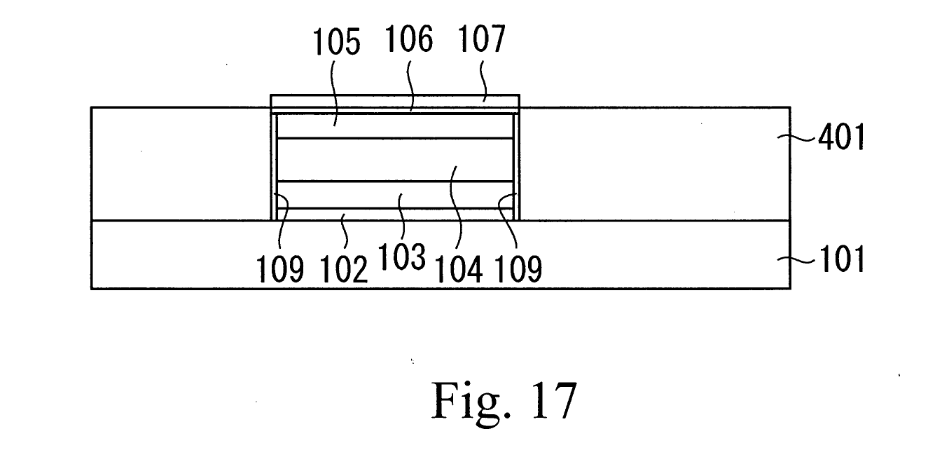

FIGS. 17 to 22 illustrate a method for producing a semiconductor device in accordance with a fourth preferred embodiment of the present invention. The first four processes of the fourth embodiment are similar to or the same as those of the first embodiment shown in FIGS. 1 to 4 until the process for forming the exposed side surface in FIG. 4 by etching. After that, the CVD oxide layer 108 used as a mask is removed, and then a thermal oxide film 109 is formed by shallowly subjecting the exposed side surface of the silicon layers to thermal oxidation.

Subsequently, an HDP oxide film with thickness of about 3.0 μm is entirely formed by the HDP CVD method. Then the wafer surface is polished by a CMP method. The polishing is halted based on the detection of the CVD nitride film 107. After that, a field oxide film 401 is formed as shown in FIG. 17.

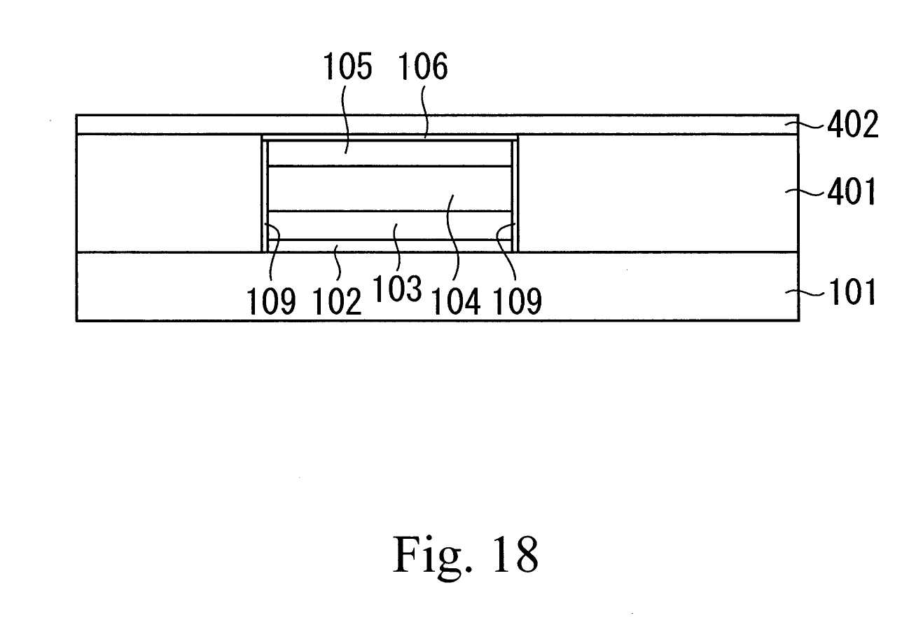

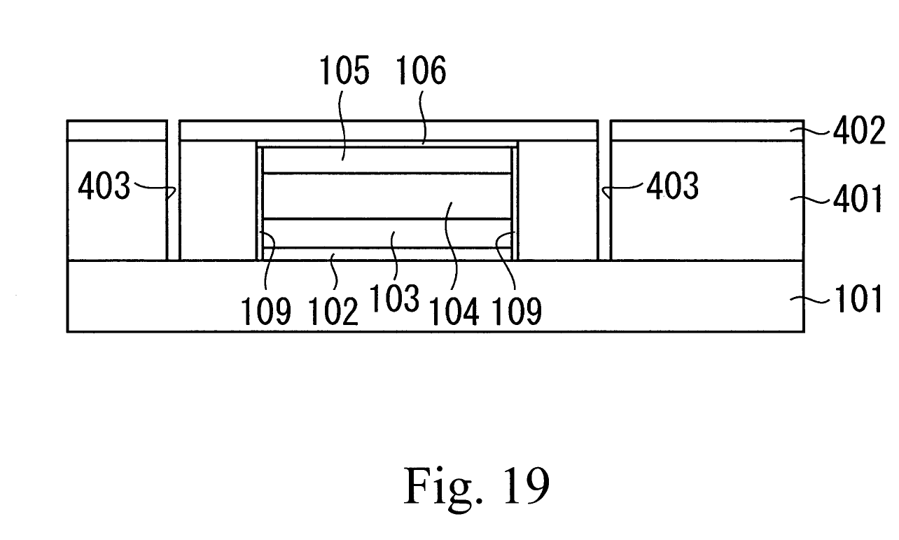

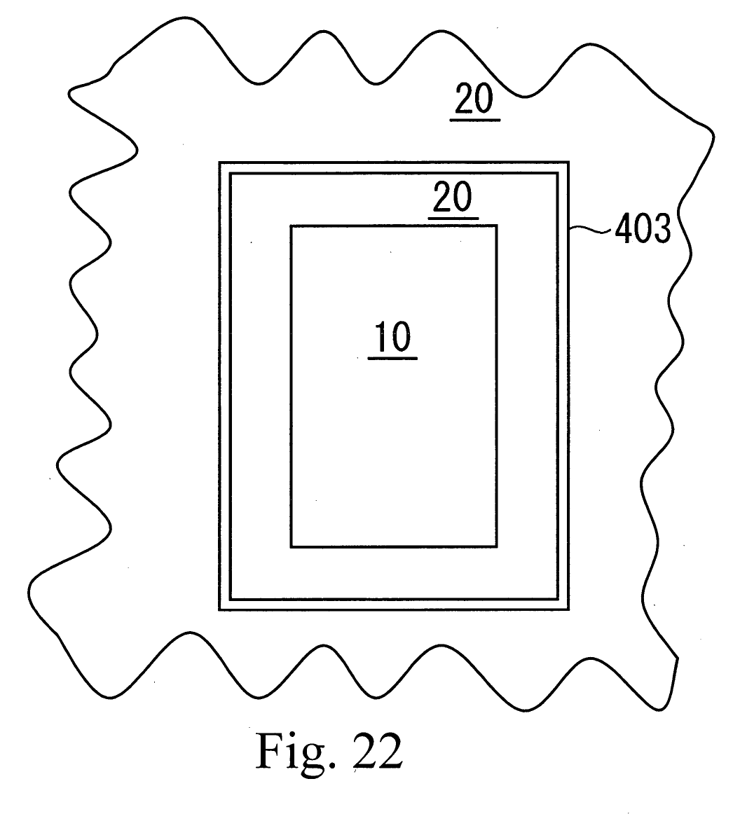

Subsequently, as shown in FIGS. 18 and 19, a CVD nitride film 402 with a thickness of about 200 nm is formed on the entire surface. Thereafter, a resist pattern to form a trench pattern 403 is formed in the CVD nitride layer 402 and the field oxide 401 to surround the active region 10 as shown in the plan view of FIG. 22. As shown in FIG. 19, etching the CVD nitride layer 402 and the field oxide 401 with this resist pattern forms the trench pattern 403 (trench portion).

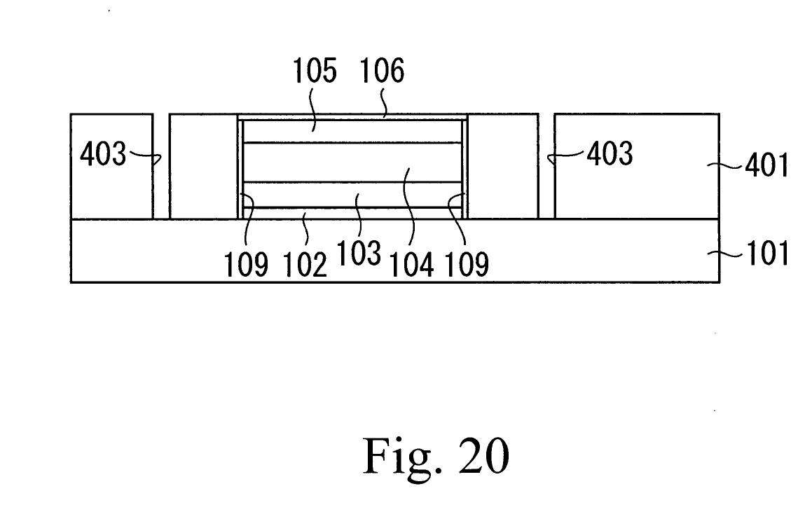

Subsequently, an annealing process at the maximum heat load (temperature) available for this method for producing a semiconductor device, or an annealing process capable of sufficiently ejecting internal residual matter to be evaporated such as moisture from the field oxide 401 is performed as a heat treatment in order to relieve the internal stress of the field oxide 401. For example, the above annealing process is performed under a nitrogen N₂ atmosphere at a temperature of 1000° C. for 30 minutes. At this time, the field oxide 401 outside from the trench pattern 403 is contracted by the heat treatment, and the trench pattern 403 subsequently expands. On the other hand, since the field oxide 401 in contact with the active region 10 is divided into the region with a small volume by the trench pattern 403, large film shrinkage of the field oxide 401 does not occur by the heat treatment. Thus, it is possible to reduce the stress in the active region. Moreover, as shown in FIG. 20, the CVD nitride layers 402 and 107 on the surface are removed.

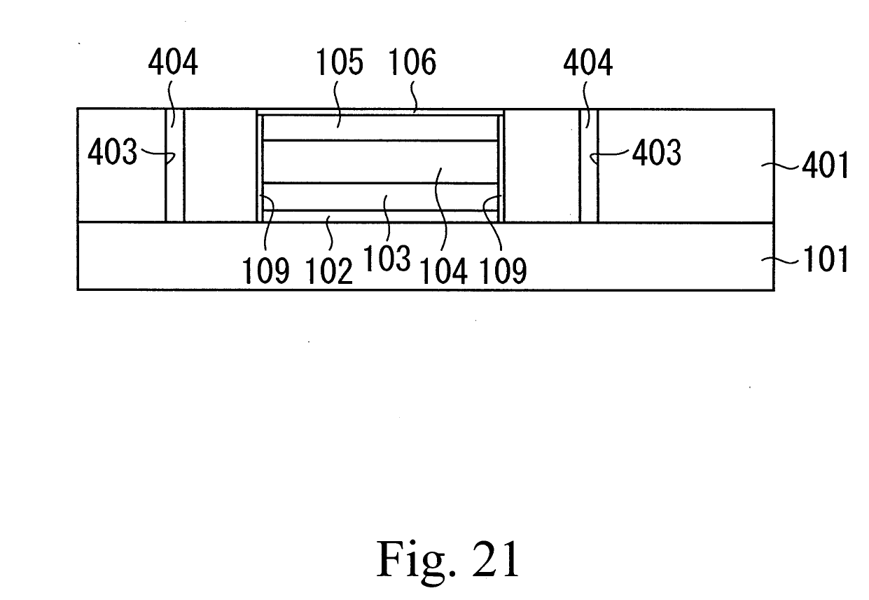

As shown in FIG. 21, the trench pattern 403 is buried by an LP-TEOS film 404, and then annealing and etchback are performed so that the LP-TEOS film 404 remains only in the trench pattern 403. Alternatively, the trench pattern 403 may be buried by a CVD nitride film instead of the LP-TEOS film 404. In this case, after the CVD nitride film is deposited, only the CVD nitride film, which remains on the surface of the field oxide 401, is removed by thermal phosphoric acid treatment. Additionally, voids may occur in the LP-TEOS film 404 where the interstice portion 404 is buried without any detrimental effects. The remaining processes are the same as or similar to those of the first embodiment.

Operation/Working-Effect

In this embodiment, an interstice portion is not formed at the boundary of the active region 10 and the field region 20. Rather, the trench pattern 403 is formed in the field region 20, and the volume of the field oxide 401 in contact with the active region 10 is reduced. Thus, the amount of the film shrinkage of the field oxide 401 in contact with the active region 10 is reduced. Therefore, it is possible to prevent dislocation caused by film shrinkage in the crystal of the active region 10. In addition, in this embodiment, since the side surface of the active region 10 is not oxidized, it is possible to prevent an influence on the active region 10 caused by the thermal oxidization. Moreover, since it is not necessary to perform a thermal phosphoric acid treatment for a long time in order to form an interstice portion, it is possible to prevent influence on the active region 10 caused by such thermal phosphoric acid treatment. Moreover, the above trench pattern 403 may be formed in combination with the interstice portion 112 at the boundary between the active region 10 and the field region 20 according to the first embodiment. In this case, since the volume of the field oxide in contact with the active region 10 is small when the stress of the field oxide is relieved, the amount of expansion of the interstice portion 112 is small. Therefore, it is easy to bury the interstice portion 112 by subjecting the inside of the interstice portion 112 to thermal oxidation.

### Fifth Embodiment

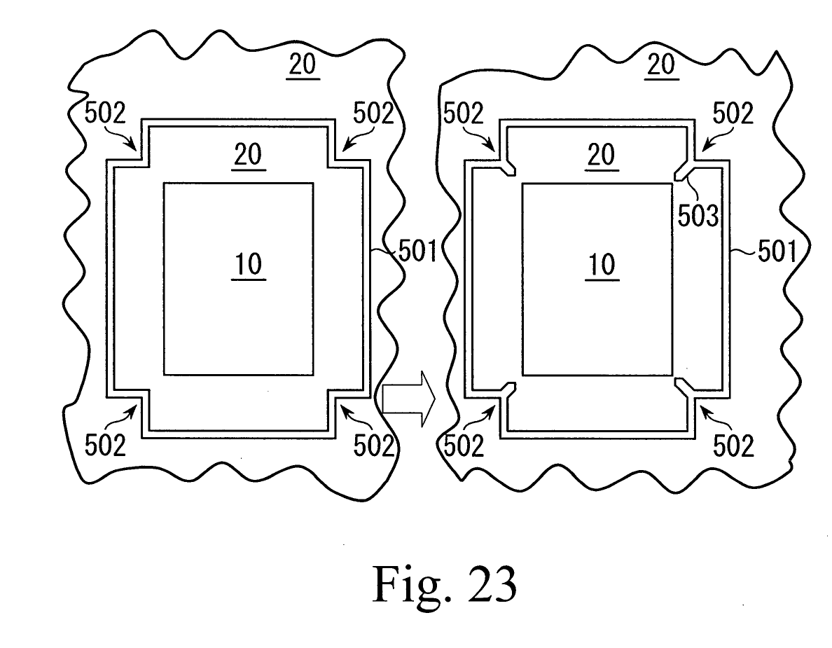

Comparing FIGS. 22 and 23, in this embodiment, although a trench pattern 501 is similarly formed in the field region 20 relative to the fourth embodiment, the trench pattern 501 has a different shape when viewed planarly. In this embodiment, as shown in FIG. 23, a corner portion 502 with an angle of not less than it rad as viewed from the single crystal silicon layer side, is formed as a fragile portion at each of four corners of the trench pattern 501 or trench body. In other words, the angle of the corner portion 502 is constructed to be not less than π rad as measured substantially perpendicularly to the depth of the trench. Alternatively stated, the angle of the corner portion 502 is to be measured on a plane parallel or substantially parallel to a bottom of the trench pattern 501. After the trench pattern 501 is formed, when heat treatment is performed to relieve the stress of the field oxide, an extending portion (crack) 503 is formed to extend inwardly from the corner portion 502 as an extending trench. Thus, it is possible to relieve immediately the stress on the field oxide. When the trench pattern 501 is buried, this crack 503 is buried by the LP-TEOS film or the CVD nitride film at the same time. The remaining processes are the same as or similar to those of the first embodiment.

Operation/Working-Effect

In this embodiment, the fragile portion (weak point) is formed in the field oxide whereby the extending portion (crack) 503 that extends from the corner portion 502 appears. Accordingly, it is possible to relieve further the stress of the field region 20 around the periphery of the active region 10. Moreover, since the extended portion 503 is also buried when the trench pattern 501 is buried, it is possible to relieve immediately the stress on the field region 20 around the periphery of the active region 10 without increasing the number of processes when compared to the fourth embodiment.

### Sixth Embodiment

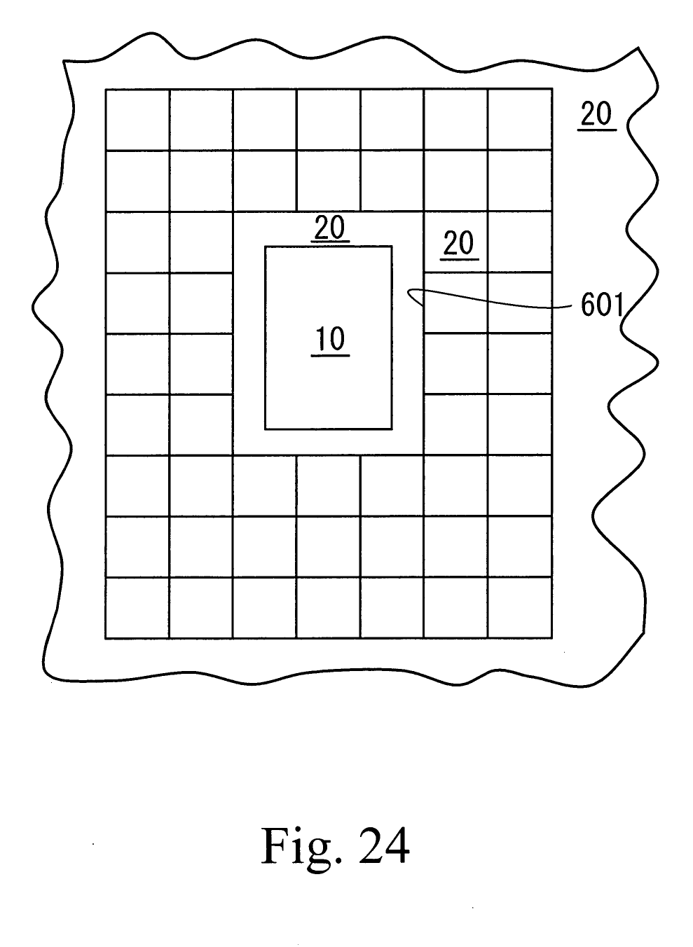

In this embodiment, as shown in FIG. 24, although a trench pattern 601 is formed in the field region 20 similar to that of the fourth embodiment, the trench pattern 601 has a shape that is different relative to the trench patterns of the fourth and fifth embodiments when viewed planarly. Specifically, as shown in FIG. 24, the trench pattern 601 is formed to have a grid shape.

According to this embodiment, not only the periphery of the active region 10, but also the whole field oxide is divided into portions with a small volume, thus it is possible to reduce the amount of film shrinkage of the whole field oxide, and to prevent film exfoliation.

### Seventh Embodiment

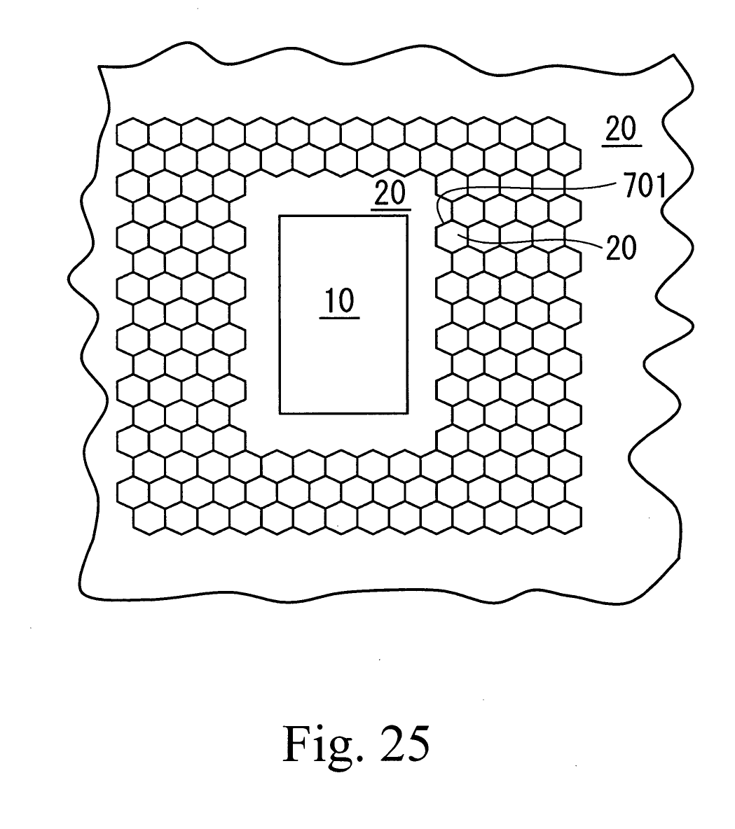

As shown in FIG. 25, although a trench pattern is formed in the whole field region 20 similar to that of the sixth embodiment, the trench pattern 701 does not have a quadrangle shape when viewed planarly but a honeycomb shape that is preferably using a hexagonal pattern to optimize symmetry. According to this embodiment, each portion is divided by the trench pattern 701 with a small volume to optimize symmetry. Thus, it is possible to reduce further local residual stress, and to reduce further the possibility of occurrence of unintended cracks.

### Eighth Embodiment

In the above embodiments, the methods are directed to prevent stress in the active region caused by film shrinkage of the thick field oxide. However, there is another factor causing the stress other than the stress by the field oxide. Since silicon layers are formed on or above the sapphire substrate 101, stress can occur due to the difference between their thermal expansion coefficients. As a result, there is a high possibility of dislocation in the single crystal silicon 103.

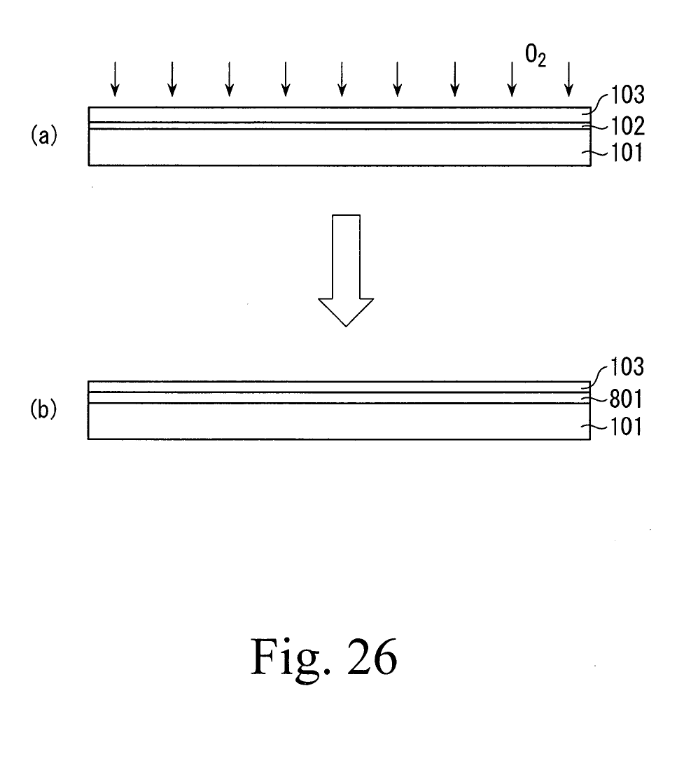

Referring to FIG. 26, to prevent this, in this embodiment, before an epitaxial layer is formed on the SOS substrate of FIG. 1, a process equivalent to the process for forming a SIMOX wafer is used to form a silicon oxide film layer (film) 801 between the sapphire substrate 101 and the single crystal silicon layer 103. Specifically, the silicon layer 102 with a high concentration of oxygen is provided by ion implantation as shown in FIG. 26(a), and then is subjected to heat treatment. Thus, the amorphous silicon layer 102 is entirely or partially changed into the thermal oxide layer 801 as shown in FIG. 26(b).

In this embodiment, the thermal oxide film 801 is interposed between the sapphire substrate 101 and the single crystal silicon 103. Thus, since the thermal oxide film 801 can withstand temperatures of 900° C. or more in heat treatment, it is possible to relieve the stress at the boundary caused by the difference between thermal expansion coefficients of the single crystal silicon layer 103 and the sapphire substrate 101 at high temperatures in the process for forming a device, and to reduce effectively the stress in the layers on or above the sapphire substrate 101. Accordingly, a method of this embodiment in conjunction with any of methods of the first to seventh embodiments can reduce both of the influences on the single crystal silicon layer caused by the stress in the field oxide, and the stress at the boundary to the sapphire substrate 101.

In the eight embodiments, a semiconductor device with a bipolar transistor formed on an SOS substrate is described, however, a similar construction can be also applied to a semiconductor device with a thick field region formed on an SOI substrate, a semiconductor device with a thick field region formed on a bulk silicon substrate, or the like, with regards to vertical structure, etc. In these cases, similar effects described above can be obtained.

The term “configured” as used herein to describe a component, section or part of a device includes hardware and/or software that is constructed and/or programmed to carry out the desired function.

Moreover, terms that are expressed as “means-plus function” in the claims should include any structure that can be utilized to carry out the function of that part of the present invention.

The terms of degree such as “substantially,” “about,” and “approximately” as used herein mean a reasonable amount of deviation of the modified term such that the end result is not significantly changed. For example, these terms can be construed as including a deviation of at least ±5% of the modified term if this deviation would not negate the meaning of the word it modifies.

This application claims priority to Japanese Patent Application No.2003-324554. The entire disclosure of Japanese Patent Application No. 2003-324554 is hereby incorporated herein by reference.

While only selected embodiments have been chosen to illustrate the present invention, it will be apparent to those skilled in the art from this disclosure that various changes and modifications can be made herein without departing from the scope of the invention as defined in the appended claims. Furthermore, the foregoing descriptions of the embodiments according to the present invention are provided for illustration only, and not for the purpose of limiting the invention as defined by the appended claims and their equivalents. Thus, the scope of the invention is not limited to the disclosed embodiments.

1. A method for producing a semiconductor device comprising:
forming an active island region on a support substrate;
forming a field region surrounding a periphery of said active island region;
forming an interstice portion at a boundary between said active island region and said field region;
subjecting said field region to heat treatment to eject residual matter to be evaporated after forming said interstice portion; and
burying said interstice portion by thermal oxidation.

2. The method for producing a semiconductor device according to claim 1, wherein said supporting substrate includes a sapphire substrate, and said active region includes a single crystal silicon layer, and said field region includes a CVD film.

3. The method for producing a semiconductor device according to claim 2, wherein forming said active island region includes,
forming a first thermal oxide film by subjecting a surface of said single crystal silicon layer formed on said sapphire substrate to thermal oxidation,
forming a first insulating film over said first thermal oxide film, and
forming said active island region of said single crystal silicon layer by etching said first insulating film, said first thermal oxide film, and said single crystal silicon layer until a surface of said sapphire substrate is exposed.

4. The method for producing a semiconductor device according to claim 3, wherein forming said active island region of said single crystal silicon layer includes,
forming a second insulating film over said first insulating film, exposing said single crystal silicon layer by etching said second insulating film, said first insulating film, and said first thermal oxide film with a resist pattern,
using said second insulating film as a mask after said resist pattern is formed over said second insulating film,
etching said single crystal silicon layer with said etched second insulating film as a hard mask, and
removing said second insulating film.

5. The method for producing a semiconductor device according to claim 2, further comprising
subjecting a side surface of said single crystal silicon layer to thermal oxidation after forming said active island region of said single crystal silicon layer, and
covering said single crystal silicon layer and said sapphire substrate with a third insulating film, wherein
forming said field region includes forming said CVD on an entire surface of said third insulating film, reducing said field oxide film until said third insulating film on said single crystal silicon layer is exposed, and
forming said interstice portion includes removing said third insulating film on a top surface and side surface of said active island region.

6. The method for producing a semiconductor device according to claim 5, further comprising forming a polycrystalline silicon film on said side surface in a side wall shape after forming said third insulating film.

7. The method for producing a semiconductor device according to claim 3, wherein burying said interstice portion includes,
forming a fourth insulating film along an inner wall of said interstice portion,
forming continuously a polycrystalline silicon film over said fourth insulating film, and
burying said interstice portion by subjecting said polycrystalline silicon film to thermal oxidation.

8. The method for producing a semiconductor device according to claim 2, further comprising forming a silicon oxide film between said sapphire substrate and said single crystal silicon layer.

9. A method for producing a semiconductor device comprising:
forming an active island region on an support substrate;
forming a field region surrounding a periphery of said active island region;
forming a trench surrounding a periphery of said active island region in said field region;
subjecting said field region to heat treatment to eject residual matter to be evaporated after forming said trench; and
burying said trench after subjecting said field region to a heat treatment.

10. The method for producing a semiconductor device according to claim 9, wherein said supporting substrate includes a sapphire substrate, and said active region includes a single crystal silicon layer, and said field region includes a CVD film.

11. The method for producing a semiconductor device according to claim 10, further comprising forming a silicon oxide film between said sapphire substrate and said single crystal silicon layer.

12. A semiconductor device comprising:
a support substrate;
an active island region having single crystal silicon being formed on said support substrate;
a CVD film being configured to surround a periphery of said active island region;
a boundary between said active island region and said CVD film having an interstice portion being formed therein, said interstice portion being configured to surround said single crystal silicon layer; and
a first insulating film being configured to bury said interstice portion.

13. The semiconductor device according to claim 12, wherein said first insulating film is a first thermal oxide film formed by subjecting a side surface of said single crystal silicon layer to thermal oxidation.

14. The semiconductor device according to claim 13, said semiconductor device further comprising a polycrystalline silicon layer buried in a wall surface exposed on said interstice portion of said CVD film.

15. The semiconductor device according to claim 12, said semiconductor device further comprising
a second insulating film formed along an inner wall of said interstice portion, and
a second thermal oxide film formed by subjecting a polycrystalline silicon layer formed on or above said second insulating film to thermal oxidation, and said second thermal oxide film to bury said interstice portion.

16. The semiconductor device according to claim 12, wherein said support substrate includes a sapphire substrate.

17. The semiconductor device according to claim 16, said semiconductor device further comprising a silicon oxide film formed on a surface of said sapphire substrate, wherein said single crystal silicon layer and said CVD film are formed on said silicon oxide film.

18. The semiconductor device according to claim 12, wherein said support substrate is an SOI substrate.

19. The semiconductor device according to claim 12, wherein said support substrate is a bulk silicon substrate.

20. A semiconductor device comprising:
a support substrate;
an active island region having single crystal silicon being formed on said support substrate;
a CVD film being configured to surround a periphery of said active island region, said CVD film having a trench formed therein to surround said active island region; and
an insulating layer buried in said trench.

21. The semiconductor device according to claim 20, wherein said trench includes a trench body having a corner portion with an angle of not less than π rad, said angle measured perpendicularly to a depth of said trench, and an extending portion configured to extend from said corner portion into said CVD film toward said active island region.

22. The semiconductor device according to claim 20, wherein said trench is formed to have a grid shape to surround said active island region.

23. The semiconductor device according to claim 20, wherein said trench is formed to have a plurality hexagons to form a honeycomb shape surrounding said active island region.

24. The semiconductor device according claim 20, said support substrate is a sapphire substrate.

25. The semiconductor device according to claim 24, said semiconductor device further comprising a silicon oxide film formed on said support substrate, wherein said single crystal silicon layer and said CVD film are formed on said silicon oxide film.

26. The semiconductor device according to claim 20, wherein said support substrate is an SOI substrate.
